(19) United States
(12) Patent Application Publication
(10) Pub. No.: US 2007/0081412 A1
(43) Pub. Date: Apr. 12, 2007

(54) Apparatus and method for controlling dual port memory in a mobile communication terminal with multi processors

(75) Inventors: Jin-Woo Jung, Suwon-si (KR); Hee-Young Lee, Seoul (KR)

Correspondence Address: DILWORTH & BARRESE, LLP, 333 EARLE OVINGTON BLVD., SUITE 702, UNIONDALE, NY, 11553, US

(73) Assignee: SAMSUNG ELECTRONICS CO., LTD., Suwon-si (KR)

(21) Appl. No.: 11/523,855

(22) Filed: Sep. 20, 2006

(30) Foreign Application Priority Data
Oct. 6, 2005 (KR) 0093800-2005

(51) Int. Cl. G11C 8/00

(52) U.S. Cl. 365/230.05

(57) ABSTRACT

Provided are an apparatus and method for preventing a dual port memory full in a mobile communication terminal with multi processors. The apparatus includes an auxiliary processor having a buffer and storing data in the dual port memory, a main processor having a memory processing module and a buffer and loading the data of the dual port memory, and the dual port memory into which the data from the auxiliary processor and the main processor are loaded. When the dual port memory is used as data exchange units of the multi processors, the synchronization collapse can be prevented, thereby providing the smooth services.

### PRIORITY

This application claims priority under 35 U.S.C. § 119 to a Korean application filed in the Korean Intellectual Property Office on Oct. 6, 2005 and assigned Ser. No. 2005-93800, the contents of which are incorporated herein by reference.

### BACKGROUND OF THE INVENTION

1.Field of the Invention

The present invention relates generally to a apparatus and method for controlling dual port memory in a mobile communication terminal with multi processors, and in particular, to an apparatus and method for preventing a dual port memory full condition under a multi-processor environment.

2.Description of the Related Art

The use of mobile communication terminals is rapidly increasing because they are easy to carry. In light of the increasing use of mobile communication terminals, service providers (terminal manufacturers) are competitively developing mobile communication terminals having a variety of special functions in order to attract users. For example, mobile communication terminals provide numerous functions including, but are not limited to, a phone book function, a game function, a Short Messaging Service (SMS) function, an Internet connection function, a morning call (or wake-up) function, a file viewer function, a file transfer function, an automatic answering function, and a camera unction, etc.

Given the increasing expectation of functions that the mobile communication terminal can execute, mobile communication terminals with two processors have been developed so as to process high-performance application programs such as visible communications and 3D graphics. For example, mobile communication terminals with Personal Digital Assistant (PDA) processor have been developed so as to provide 3D graphic processor or PDA function, in addition to the typical processor.

Mobile communication terminals with a Dual Port Random Access Memory (DPRAM) have been developed in order to support data communication and sharing between processors under the multi-processor environment. Herein, the DPRAM is referred to as a dual port memory.

The dual port memory has two ports and can simultaneously perform a read operation and a write operation. A main processor (processor B), of the two processors can perform a read operation on the dual port memory, while an auxiliary processor (processor A) can perform a write operation on the dual port memory.

However, during the communications between two processors the dual port memory can become “full” due to the load of one of the two processors. When the processor A excessively performs for example, a write operation on the dual port memory, even if the processor B performs for example, a write operation to add a spare memory region for performing the write operation, the dual port memory can still become full due to the excessive write operation. That is, the dual port memory can still be in a state where there is no excess memory region. The memory full state can cause the processor to sustain data loss or can collapse the synchronization.

In order to solve these problems, a threshold value is set for the memory full state of the dual port memory, and when the dual port memory reaches the set threshold value, the memory full state is detected and thereby causing a reduction in the transfer rate. Alternatively, when the dual port memory is full, the processor performing the write operation temporarily stores data.

In the method of detecting the dual port memory full, the memory size greatly affects the performance of the dual port memory. The probability that the memory will be full decreases as the memory size increases. However, the memory size cannot be arbitrarily set largely without limitations.

In case where the write processor uses a temporary buffer, the read processor has to read the data from the temporary buffer, that is, the data has the effectiveness in the read processor. Consequently, the write processor cannot parse the data and control the data transfer rate.

### SUMMARY OF THE INVENTION

An object of the present invention is to substantially solve at least the above described problems and/or disadvantages and to provide at least the advantages set forth herein below. Accordingly, an aspect of the present invention is to provide an apparatus and method for preventing a dual port memory full condition in a mobile communication terminal having multiple processors. Specifically, the transfer rate can be controlled in real time by recognizing the load of a current processor during a process in which real information has an effective meaning. Also, the dual port memory that is a limited resource can be effectively used.

According to an aspect of the present invention, an apparatus for preventing a dual port memory full condition in a mobile communication terminal with multi processors includes an auxiliary processor having a buffer and for storing data in the dual port memory; a main processor having a memory processing module and a buffer as for loading the data of the dual port memory; and the dual port memory for loading the data from the auxiliary processor and the main processor.

According to another aspect of the present invention, a method of storing data from an auxiliary processor to a dual port memory in a mobile communication terminal with multi processors includes inputting data into the auxiliary processor; checking whether a buffer of the auxiliary processor is empty; when the buffer of the auxiliary processor is empty, checking whether the dual port memory is full; when the dual port memory is full, storing the data in the buffer of the auxiliary processor; when a stuffing data exists within the data, removing the stuffing data at the auxiliary processor; and storing the resulting data in the dual port memory.

According to a further aspect of the present invention, a method of loading data from a dual port memory to a main processor in a mobile communication terminal with multi processors includes copying, at the main processor, data from the dual port memory to a buffer of the main processor; when a stuffing data exists within the data, removing the stuffing data; checking whether or not an occupancy rate of the buffer of the main processor is greater than an upper threshold value; when the occupancy rate of the buffer is not greater than the upper threshold value, determining whether a transfer rate is normal; when the transfer rate is normal, resetting the transfer rate to a level equal to a previous transfer rate at a memory processing module of the main processor; and removing the processed data from the buffer of the main processor.

### BRIEF DESCRIPTION OF THE DRAWINGS

The above and other objects, features and advantages of the present invention will become more apparent from the following detailed description when taken in conjunction with the accompanying drawings in which:

FIG. 1 is a block diagram illustrating a mobile communication terminal having multi processors and an apparatus for preventing a dual port memory full condition according to the present invention;

FIG. 2 is a flowchart illustrating a data processing procedure of a processor A according to the present invention;

FIG. 3 is a flowchart illustrating a data processing procedure of a processor B according to the present invention; and

FIG. 4A and FIG. 4B are graphs of a threshold value with respect to a transfer rate of a buffer B according to the present invention.

### DETAILED DESCRIPTION OF THE PREFERRED EMBODIMENTS

Preferred embodiments of the present invention will be described herein with reference to the accompanying drawings. In the following description, well-known functions or constructions are not described in detail since they would obscure the invention in unnecessary detail.

Hereinafter, an apparatus and method for preventing a dual port memory full condition in a mobile communication terminal with multi processors will be described in detail with reference to the accompanying drawings.

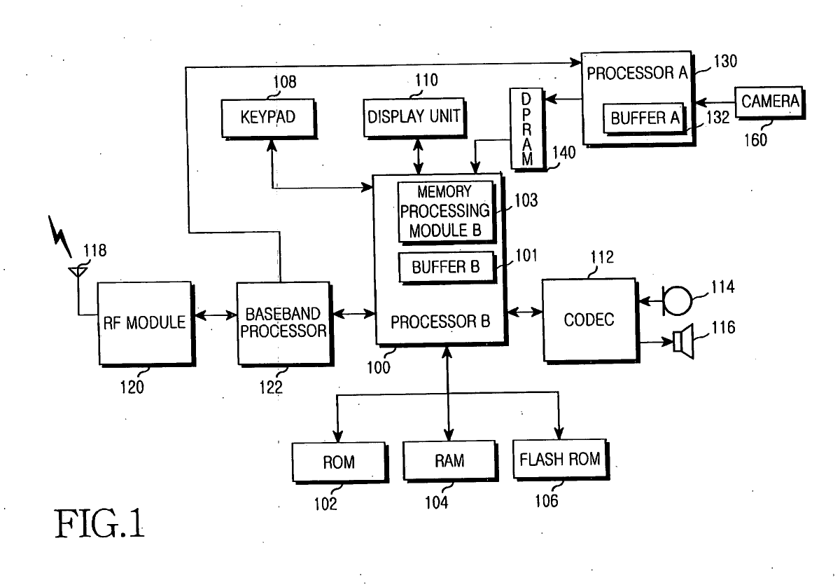

FIG. 1 is a block diagram illustrating a mobile communication terminal having multi processors according to the present invention. Examples of the mobile communication terminal include a cellular phone, a Personal Communication Service (PCS) terminal, a Personal Data Assistant (PDA) terminal, an International Mobile Communication-2000(IMT-2000) terminal, and a Wibro terminal. A following description will be made with a general structure of the terminals.

Referring to FIG. 1, a processor B (e.g., a microprocessor unit (MPU)) 100 controls an overall operation of the mobile communication terminal. The processor B 100 is a main processor.

For example, the processor B 100 processes and controls voice communication as well data communication. The processor B 100 also processes and controls a data exchange function as well as a stuffing data removing function between a dual port memory 140 and a Buffer B 101. The processor B 100 includes the Buffer B 101 and a memory processing module B 103.

The stuffing data means data inserted for a specific purpose. A detail description about typical process and control operations of the processor B 100 is omitted herein. The memory processing module B 103 controls a transfer rate when data is transferred from the dual port memory 140 to the buffer B 101.

A processor A 130 processes and controls specific functions e.g., a 3D acceleration function, a specific image processing or a PDA processor function, a data exchange function and a stuffing data removing function between the dual port memory 140 and a buffer A 132. Also, the processor A 130 includes the buffer A 132 for the dual port memory 140. The processor A 130 is an auxiliary processor.

Since the dual port memory 140 has two ports, it can perform a read operation and a write operation at the same time. The dual port memory 140 is used to exchange data between the processor A 130 and the processor B 100. A camera 160 is used for purposes of carrying out the image communication or take a picture of a specific object. A Read Only Memory (ROM) 102 stores microcodes of a program for controlling the processor B 100 and a variety of reference data.

A Random Access Memory (RAM) 104 is a working memory of the processor B 100 and temporarily stores data that are generated during the execution of various programs. A flash ROM 106 stores a variety of updateable data, such as a phone book, a sent message, and a received message.

A keypad 108 includes numeric keys of digits 0-9 and a plurality of function keys, such as a Menu key, a Cancel (Delete) key, a Conformation key, a Talk key, an End key, an Internet connection key, and Navigation keys (or direction keys). Upon pressing a specific key of the keypad 106, a corresponding key input data is provided to the processor B 100.

A display unit 110 displays status information generated during the operation of the mobile communication terminal, numerals, characters, moving pictures, still pictures, and so on. A Color Liquid Crystal Display (LCD) may be used for the display unit 110.

The touch pad 109 is disposed on a front surface of the display unit 110 and provides the controller 100 with touch data generated by the user's touch thereon. For example, when the user touches the touch pad 109, a touch data according to the touch region is provided to the controller 100 and then the controller 100 calculates the coordinate value of the touch region based on the touch data.

A coder-decoder (codec) 112 connected to the processor B 100, and a microphone 114 and a speaker 116 connected to the codec 112 serve as an audio input/output block for telephone call and voice recording.

The codec 112 converts Pulse Code Modulation (PCM) data provided from the processor B 100 into analog audio signals. The analog audio signals are outputted through the speaker 116. Also, the codec 112 converts audio signals received through the microphone 114 into PCM data and provides the converted PCM data to the processor B 100.

A radio frequency (RF) unit 120 down-converts RF signals received through an antenna 118 and provides the down-converted RF signals to a baseband processor 122. Also, the RF unit 120 up-converts baseband signals from the baseband processor 122 and transmits the up-converted baseband signals through the antenna 118.

The baseband processor 122 processes the baseband signals transmitted/received between the RF unit 120 and the processor B 100. For example, in the case of data transmission, the baseband processor 122 performs a channel coding and a spreading on transmit (TX) data, and in the case of data reception, the baseband processor 122 performs a despreading and a channel decoding on receive (RX) data.

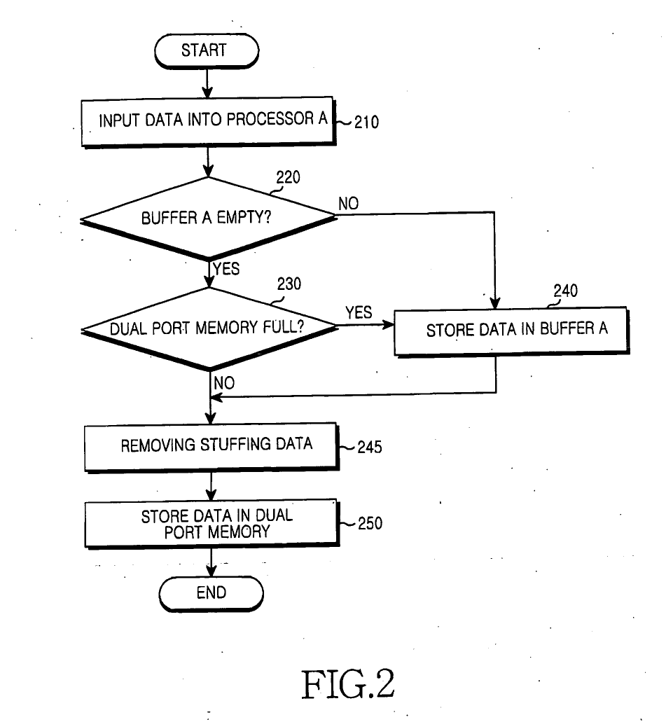

FIG. 2 is a flowchart illustrating a data processing procedure of the process A according to the present invention. Referring to FIG. 2, when the processor A 130 is a dedicated image processor, the processor A 130 receives a photograph data from the camera 160 or an image streaming data from the baseband processor 122 in operation 210. In operation 220, the processor A 130 determines whether the buffer A 132 is empty. In operation 240, upon determining that the buffer A 132 is not empty, the processor A 130 stores the photograph data or the image streaming data in the buffer A 132.

The buffer A 132 has a size of “input unit×L”, where L represents a variable constant. The value of “input unit×L” can be changed according to the manufacturer's setting. After operation 240, the process proceeds to operation 245. In operation 230, when the buffer A 132 is empty in operation 220, the processor A 130 checks whether the dual port memory 140 is full.

In operation 240, when the dual port memory 140 is full, the processor A 130 stores the photograph data or the image streaming data in the buffer A 132. Thereafter, the process proceeds to operation 245. In operation 245, when the dual port memory 140 is not full, the processor A 130 deletes the stuffing data from the photograph data or the image streaming data.

In operation 250, the processor A 130 stores the photograph data or the image streaming data without stuffing data in the dual port memory 140 and thereby terminating the process.

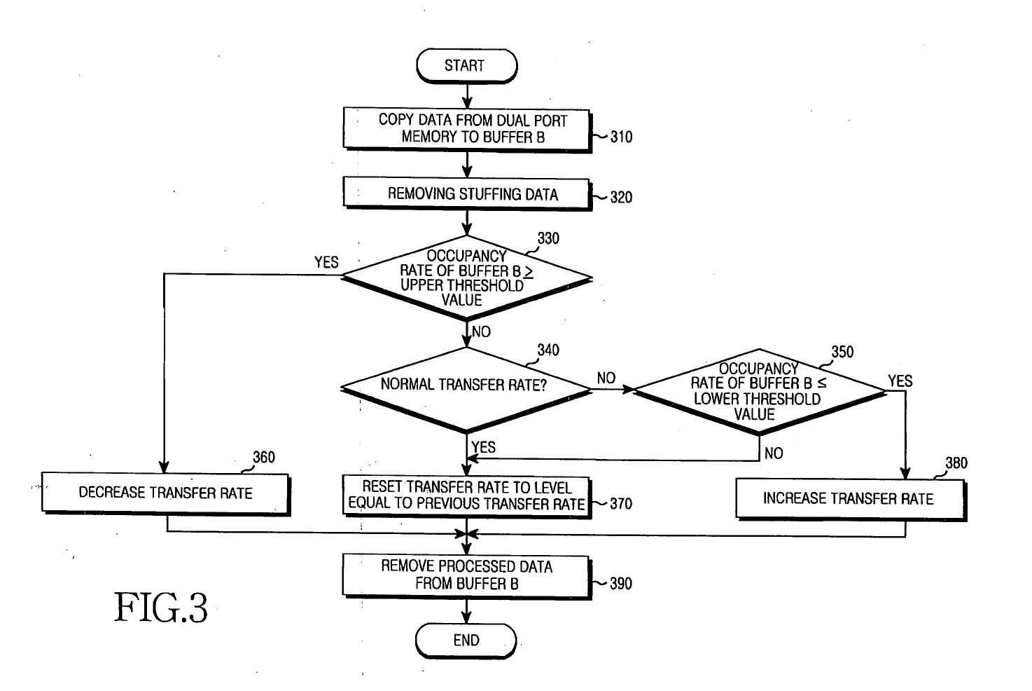

FIG. 3 is a flowchart illustrating a data processing procedure of the processor B according to the present invention. Referring to FIG. 3, in operation 310, the processor B 100 of the mobile communication terminal copies the photograph data or the image streaming data stored by the processor A 130 into the buffer B 101.

In operation 320, the stuffing data are removed from the photograph data or the image streaming data.

In operation 330, the processor B 100 determines whether the occupancy rate of the buffer B 101 is greater than “read unit×N” where N represents a variable constant. The value of “read unit×N” can later be changed.

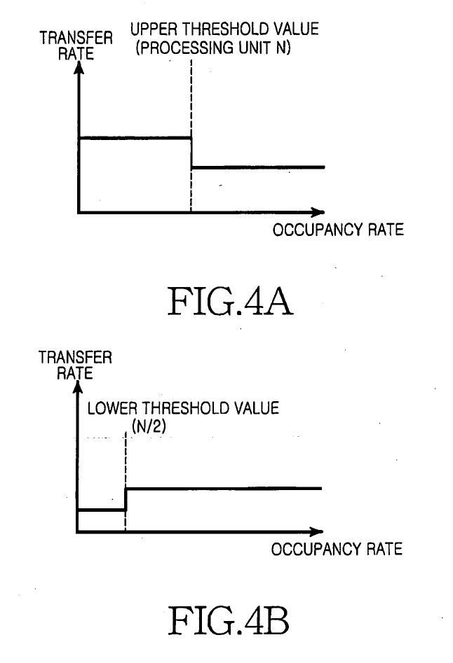

In operation 360, when the occupancy rate of the buffer B 101 is greater than the maximum threshold value, the processor B 100 controls the memory processing module 103 to decrease the transfer rate as illustrated in FIG. 4(a).

Although the maximum threshold value has been set to “read unit×N”, the value can also be later changed.

Then, the process proceeds to operation 390. The transfer rate is a speed when data is transferred from the dual port memory 140 to the buffer B 101.

In operation 340, when the occupancy rate of the buffer B 101 is less than “read unit×N”, that is, the maximum threshold value, the processor B 100 determines whether the transfer rate is in a normal range.

In operation 370, when the transfer rate is in the normal range in operation 340, the processor B 100 controls the memory processing module 103 to adjust the transfer rate to the level equal to the previous transfer rate. Then, the process proceeds to operation 390.

In operation 350, when the transfer rate is not within the normal range in operation 340, the processor B 100 checks whether or not the occupancy rate of the buffer B 101 is less than the minimum threshold value, although the minimum threshold value is set to “N/2” where N represents a multiple, it can also be changed later.

In operation 380, when the occupancy rate of the buffer B 101 is less than the minimum threshold value, the processor B 100 controls the memory processing module B 103 to increase the transfer rate. Then, the process proceeds to operation 390. In operation 370, when the occupancy rate of the buffer B 101 is greater than the minimum threshold value in operation 350, the process B 100 controls the memory processing module 103 to adjust the transfer rate to a level equal to the previous transfer rate.

In operation 390, the processor B 100 removes the processed data from the buffer B 101 and then the algorithm is terminated.

As described above, when the dual port memory 140 is used as a data exchange unit of the multi processors included in the mobile communication terminal, the synchronization collapse can be prevented, thereby providing the smooth services.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. An apparatus for preventing a dual port memory full in a mobile communication terminal with multi processors, the apparatus comprising:
an auxiliary processor having a buffer and for storing data in the dual port memory;
a main processor having a memory processing module and a buffer as well as for loading the data of the dual port memory; and
the dual port memory for loading the data from the auxiliary processor and the main processor.

2. The apparatus of claim 1, wherein the auxiliary processor is at least one of a processor for processing multimedia data or a processor for processing a Personal Data Assistant (PDA) fiction.

3. The apparatus of claim 1, wherein the memory processing module of the main processor controls a transfer rate when the data are transferred from the dual port memory to the buffer of the main processor.

4. The apparatus of claim 1, wherein when the main processor loads the data from the dual port memory storing,the loaded data in the buffer of the main processor.

5. The apparatus of claim 1, wherein when the dual port memory is full, the auxiliary processor stores the data in the buffer of the auxiliary processor.

6. The apparatus of claim 1, wherein the main processor has a function of removing a stuffing data.

7. The apparatus of claim 1, wherein the auxiliary processor has a function of removing a stuffing data.

8. The apparatus of claim 1, wherein the buffer of the auxiliary processor has a size of input unit×L where L represents a constant.

9. A method of storing data from an auxiliary processor to a dual port memory in a mobile communication terminal with multi processors, the method comprising:
inputting data into the auxiliary processor;
checking whether a buffer of the auxiliary processor is empty;
upon determining that the buffer of the auxiliary processor is empty, checking whether the dual port memory is full;
when the dual port memory is full, storing the data in the buffer of the auxiliary processor;
when a stuffing data exists in the data, removing the stuffing data at the auxiliary processor; and
storing the data in the dual port memory.

10. The method of claim 9, further comprising:
when the buffer of the auxiliary processor is not empty, storing the data in the buffer of the auxiliary processor; and
when the stuffing data exists in the data, removing the stuffing data at the auxiliary processor.

11. The method of claim 9, further comprising, when the dual port memory is not full and the stuffing data exists in the data, removing the stuffing data at the auxiliary processor.

12. The method of claim 9, wherein the buffer of the auxiliary processor has a size of input unit×L where L represents a multiple.

13. A method of loading data from a dual port memory to a main processor in a mobile communication terminal with multi processors, the method comprising:
copying, at the main processor, data from the dual port memory to a buffer of the main processor;
when a stuffing data exists in the data, removing the stuffing data;
checking whether or not an occupancy rate of the buffer of the main processor is greater than an upper threshold value;
when the occupancy rate of the buffer is not greater than the upper threshold value, checking whether or not a transfer rate is normal;
when the transfer rate is normal, resetting the transfer rate to a level equal to a previous transfer rate at a memory processing module of the main processor; and
removing the processed data from the buffer of the main processor.

14. The method of claim 13, wherein the transfer rate is a transfer speed when the data is transferred from the dual port memory to the buffer of the main processor.

15. The method of claim 13, wherein the threshold value is read unit×N where N represents a constant.

16. The method of claim 13, further comprising:
when the occupancy rate of the buffer is greater than the maximum threshold value, decreasing the transfer rate at the memory processing module of the main processor; and
removing the processed data from the buffer of the main processor.

17. The method of claim 13, further comprising:
when the transfer rate is not normal, checking whether or not the occupancy rate of the buffer of the main processor is less than a lower threshold value; and
when the occupancy rate of the buffer is not less than the lower threshold value, resetting the transfer rate to a level equal to a previous rate at the memory processing module of the main processor.

18. The method of claim 17, wherein the minimum threshold value is N/2 where N represents a constant.

19. The method of claim 17, further comprising, when the occupancy rate of the buffer of the main processor is less than the minimum threshold value, increasing the transfer rate at the memory processing module of the main processor.
